(19) United States
(12) Patent Application Publication
(10) Pub. No.: US 2026/0047392 A1
(43) Pub. Date: Feb. 12, 2026

(54) DIE ATTACH FILM STRUCTURE AND SEMICONDUCTOR PACKAGE INCLUDING THE SAME

(71) Applicant: Samsung Electronics Co., Ltd., Suwon-si (KR)

(72) Inventors: Jihwan Kim, Suwon-si (KR); Hansol Yoo, Suwon-si (KR)

(21) Appl. No.: 19/245,585

(22) Filed: Jun. 23, 2025

(30) Foreign Application Priority Data
Aug. 7, 2024 (KR) 10-2024-0105340

(51) Int. Cl. H01L 23/00; H01L 21/683; H01L 23/31; H01L 25/065

(52) U.S. Cl. CPC H01L 24/32; H01L 21/6836; H01L 24/29; H01L 25/0657; H01L 23/3128; H01L 24/48; H01L 24/73; H01L 2221/68327; H01L 2221/68377; H01L 2224/29082; H01L 2224/2929; H01L 2224/29339; H01L 2224/29347; H01L 2224/29355; H01L 2224/29387; H01L 2224/29393; H01L 2224/29499; H01L 2224/32145; H01L 2224/32227; H01L 2224/32237; H01L 2224/48228; H01L 2224/73265; H01L 2225/0651; H01L 2225/06524; H01L 2225/06568

(57) ABSTRACT

A die attach film structure includes a dicing film, an insulating adhesion layer including an upper surface and a lower surface opposite the upper surface, the lower surface of the insulating adhesion layer contacting an upper surface of the dicing film and including an insulating filler, and a conductive adhesion layer contacting an upper surface of the insulating adhesion layer and including a conductive filler.

### CROSS-REFERENCE TO RELATED APPLICATION

This application claims priority under 35 U.S.C. § 119 to Korean Patent Application No. 10-2024-0105340, filed on Aug. 7, 2024 in the Korean Intellectual Property Office (KIPO), the contents of which are herein incorporated by reference in their entirety.

### FIELD

Example embodiments relate to a die attach film structure, a semiconductor package including the same, a method of manufacturing a die attach film structure, and a method of manufacturing a semiconductor package using the same.

### BACKGROUND

A semiconductor chip may be bonded onto a package substrate using a die attach film. The die attach film may have a low thermal conductivity, and thus heat generated by the semiconductor chip may not be effectively dissipated outwardly.

### SUMMARY

Example embodiments provide a die attach film structure having enhanced characteristics.

Example embodiments provide a method of manufacturing a die attach film structure having enhanced characteristics.

Example embodiments provide a semiconductor package having enhanced characteristics.

Example embodiments provide a method of manufacturing a semiconductor package having enhanced characteristics.

According to example embodiments, a die attach film (DAF) structure may include a dicing film, an insulating adhesion layer comprising an upper surface and a lower surface opposite the upper surface, the lower surface of the insulating adhesion layer contacting an upper surface of the dicing film and the insulating adhesion layer comprising an insulating filler, and a conductive adhesion layer contacting the upper surface of the insulating adhesion layer and comprising a conductive filler.

According to example embodiments a semiconductor package may include a package substrate structure, a first die attach film (DAF) bonded to an upper surface of the package substrate structure, and a first semiconductor chip comprising a lower surface that is bonded to an upper surface of the first DAF opposite the package substrate structure. The first DAF may include a first insulating adhesion layer comprising an upper surface and a lower surface opposite the upper surface, the lower surface of the first insulating adhesion layer contacting an upper surface of the package substrate structure and the first insulating adhesion layer including a first insulating filler, and a first conductive adhesion layer contacting the upper surface of the first insulating adhesion layer and the lower surface of the first semiconductor chip, the first conductive adhesion layer comprising a first conductive filler.

According to example embodiments, a semiconductor package may include a package substrate structure comprising a substrate pad, a first die attach film (DAF) bonded to an upper surface of the package substrate structure, a first semiconductor chip comprising a lower surface that is bonded to an upper surface of the first DAF opposite the package substrate structure, the first semiconductor chip comprising a first chip pad at an upper portion thereof, a second DAF bonded to an upper surface of the first semiconductor chip that is opposite the lower surface thereof, a second semiconductor chip comprising a lower surface that is bonded to an upper surface of the second DAF opposite the first semiconductor chip, the second semiconductor chip, the second semiconductor chip comprising a second chip pad at an upper portion thereof, a first bonding wire contacting the first chip pad and the substrate pad and electrically connecting the first chip pad and the substrate pad to each other, a second bonding wire contacting the second chip pad and the substrate pad and electrically connecting the second chip pad and the substrate pad to each other, and a molding member on the package substrate structure and on the first and second semiconductor chips, the first and second bonding wires, and the first and second DAFs. The first DAF may include a first insulating adhesion layer comprising an upper surface and a lower surface opposite the upper surface, the lower surface of the first insulating adhesion layer contacting the upper surface of the package substrate structure and the first insulating adhesion layer comprising a first insulating filler, and a first conductive adhesion layer contacting the upper surface of the first insulating adhesion layer and the lower surface of the first semiconductor chip and comprising a first conductive filler. The second DAF may include a second insulating adhesion layer comprising an upper surface and a lower surface opposite the upper surface, the lower surface of the second insulating adhesion layer contacting the upper surface of the first semiconductor chip and the second insulating adhesion layer comprising a second insulating filler, and a second conductive adhesion layer contacting the upper surface of the second insulating adhesion layer and the lower surface of the second semiconductor chip and comprising a second conductive filler.

According to example embodiments, there is provided a method of manufacturing a die attach film (DAF) structure. In the method, an insulating adhesion layer including an insulating filler may be coated on a first sacrificial release film to form a first bonding layer structure. A conductive adhesion layer including a conductive filler may be coated on a second sacrificial release film to form a second bonding layer structure. The first and second bonding layer structures may be bonded to each other such that the insulating adhesion layer may contact the conductive adhesion layer, to form a third bonding layer structure. A pressure sensitive adhesive (PSA) layer may be coated on a base film to form a dicing film. After removing the first sacrificial release film of the third bonding layer structure, the third bonding layer structure may be bonded to the dicing film such that the insulating adhesion layer may contact the PSA layer.

In example embodiments, the conductive filler may comprise silver (Ag) particles or copper (Cu) particles.

In example embodiments, the conductive adhesion layer may further comprise an acrylate resin and an epoxy resin.

In example embodiments, the conductive adhesion layer may comprise the conductive filler in an amount of about 20 wt % to about 80 wt %, and the acrylate resin and the epoxy resin collectively in an amount of about 20 wt % to about 80 wt %.

In example embodiments, the conductive adhesion layer may further comprise an additive in an amount of equal to or less than about 1 wt %.

In example embodiments, the insulating filler may comprise alumina (Al₂O₃) particles, boronitride (BN) particles, or aluminum nitride (AlN) particles.

In example embodiments, the insulating adhesion layer may further comprise an acrylate resin and an epoxy resin.

In example embodiments, the insulating adhesion layer may comprise the insulating filler in an amount of about 20 wt % to about 80 wt %, and the acrylate resin and the epoxy resin collectively in an amount of about 20 wt % to about 80 wt %.

In example embodiments, the insulating adhesion layer may further comprise an additive in an amount of equal to or less than about 1 wt %.

In example embodiments, the second sacrificial release film may be removed. The conductive adhesion layer and the insulating adhesion layer may be patterned.

In example embodiments, a release film may be attached on the conductive adhesion layer, after the conductive adhesion layer and the insulating adhesion layer are patterned.

According to example embodiments, there is provided a method of manufacturing a semiconductor package. In the method, a first wafer may be bonded onto a first die attach film (DAF) structure including a first dicing film and a first DAF. A singulation process may be performed on the first wafer and the first DAF structure by a sawing process to form a plurality of first semiconductor chips. After picking up each of the plurality of first semiconductor chips to which the first DAF is attached, each of the plurality of first semiconductor chips may be bonded to a respective package substrate structure such that the first DAF may contact an upper surface of the respective package substrate structure. The first DAF may include a first insulating adhesion layer including a first insulating filler, and a first conductive adhesion layer contacting an upper surface of the first insulating adhesion layer opposite the respective package substrate. The first conductive adhesion layer includes a first conductive filler.

In example embodiments, the respective package substrate structure may comprise a package substrate having first and second surfaces opposite to each other in a vertical direction in which the first DAF and one of the plurality of first semiconductor chips are stacked thereon, a substrate pad adjacent to the first surface of the package substrate, and a substrate protective layer on the first surface of the package substrate. An upper surface of the substrate pad may be exposed by the substrate protective layer, and the first insulating adhesion layer may contact the substrate pad and the substrate protective layer.

In example embodiments, each of the plurality of first semiconductor chips may comprise a substrate having first and second surfaces opposite to each other in the vertical direction, wherein the first surface of the substrate comprises at least one conductive circuit pattern and the second surface of the substrate is free of conductive structures, and a chip pad on the first surface of the substrate and electrically connected to the at least one conductive circuit pattern. The first conductive adhesion layer may contact the second surface of the substrate.

In example embodiments, a bonding wire may be formed to contact the chip pad and the substrate pad. The bonding wire may electrically connect the chip pad and the substrate pad to each other.

In example embodiments, a second wafer may be bonded onto a second DAF structure comprising a second dicing film and a second DAF. A singulation process may be performed on the second wafer and the second DAF structure by a sawing process to form a plurality of second semiconductor chips. After picking up each of the plurality of second semiconductor chips to which the second DAF is attached, each of the plurality of second semiconductor chips may be bonded to a corresponding one of the plurality of first semiconductor chips such that the second DAF may contact an upper surface of the corresponding one of the plurality of first semiconductor chips. The second DAF may comprise a second insulating adhesion layer comprising a second insulating filler, and a second conductive adhesion layer contacting an upper surface of the second insulating adhesion layer opposite the upper surface of the corresponding one of the plurality of first semiconductor chips. The second conductive adhesion layer may comprise a second conductive filler.

In example embodiments, each of the plurality of second semiconductor chips may comprise a substrate having first and second surfaces opposite to each other in a vertical direction, wherein the first surface of the substrate comprises at least one conductive circuit pattern and the second surface of the substrate is free of conductive structures, and a chip pad on the first surface of the substrate and electrically connected to the at least one conductive circuit pattern. The second conductive adhesion layer may contact the second surface of the substrate.

According to example embodiments, there is provided a method of manufacturing a semiconductor package. In the method, a first wafer may be bonded onto a first die attach film (DAF) structure including a first dicing film and a first DAF. A singulation process may be performed on the first wafer and the first DAF structure by a sawing process to form a plurality of first semiconductor chips. Each of the plurality of first semiconductor chips may include a respective first chip pad thereon. After picking up each of the plurality of first semiconductor chips to which the first DAF is attached, each of the plurality of first semiconductor chips may be bonded to a respective package substrate structure such that the first DAF may contact an upper surface of the respective package substrate structure, the respective package substrate structure including a respective substrate pad thereon. A first bonding wire may be formed to contact the respective first chip pad and the respective substrate pad, and the first bonding wire may electrically connect the respective first chip pad and the respective substrate pad to each other. A second wafer may be bonded onto a second DAF structure including a second dicing film and a second DAF. A singulation process may be performed on the second wafer and the second DAF structure by a sawing process to form a plurality of second semiconductor chips. Each of the plurality of second semiconductor chips may include a respective second chip pad thereon. After picking up each of the plurality of second semiconductor chips to which the second DAF is attached, each of the plurality of second semiconductor chips may be bonded to a corresponding one of the plurality of first semiconductor chips such that the second DAF may contact an upper surface of the corresponding one of the plurality of first semiconductor chips. A second bonding wire may be bonded to contact the respective second chip pad and the respective substrate pad, and may electrically connect the respective second chip pad and the respective substrate pad to each other. A molding member may be formed on the respective package substrate structure and on the plurality of first semiconductor chips, the plurality of second semiconductor chips, the first and second bonding wires, and the first and second DAFs. The first DAF may include a first insulating adhesion layer including a first insulating filler, and a first conductive adhesion layer contacting an upper surface of the first insulating adhesion layer opposite the respective package substrate structure, and the first conductive adhesion layer may include a first conductive filler. The second DAF may include a second insulating adhesion layer including a second insulating filler, and a second conductive adhesion layer contacting an upper surface of the second insulating adhesion layer opposite the upper surface of the corresponding one of the plurality of first semiconductor chips, and the second conducive adhesion layer may include a second conductive filler.

In example embodiments, the respective package substrate structure may comprise a package substrate having first and second surfaces opposite to each other in a vertical direction, a substrate pad adjacent to the first surface of the package substrate, and a substrate protective layer on the first surface of the package substrate. An upper surface of the substrate pad may be exposed by the substrate protective layer. The first insulating adhesion layer may contact the substrate pad and the substrate protective layer.

In example embodiments, each of the plurality of first semiconductor chips may comprise a substrate having first and second surfaces opposite to each other in a vertical direction, wherein the first surface of the substrate comprises at least one conductive circuit pattern and the second surface of the substrate is free of conductive structures, and a chip pad on the first surface of the substrate and electrically connected to the at least one conductive circuit pattern. The first conductive adhesion layer may contact the second surface of the substrate.

The die attach film (DAF) structure in accordance with example embodiments may have a stack structure of the insulating adhesion layer including the insulating filler and the conductive adhesion layer including the conductive filler, and the conductive adhesion layer may have a relatively high thermal conductivity so that the DAF structure may have an increased thermal conductivity. Accordingly, the semiconductor package including the DAF structure may have an enhanced heat emission or dissipation characteristics.

### BRIEF DESCRIPTION OF THE DRAWINGS

FIG. 1 is a cross-sectional view illustrating a die attach film (DAF) structure in accordance with example embodiments, and FIG. 2 is an enlarged cross-sectional view of region X of FIG. 1.

FIGS. 3, 4, 5, 6, and 7 are cross-sectional views illustrating a method of manufacturing a DAF structure in accordance with example embodiments.

FIG. 8 is a cross-sectional view illustrating a semiconductor package in accordance with example embodiments.

FIGS. 9, 10, and 11 are cross-sectional views illustrating a method of manufacturing a semiconductor package in accordance with example embodiments.

### DETAILED DESCRIPTION OF EMBODIMENTS

Hereinafter, example embodiments will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second”, and/or “third” may be used selectively or interchangeably for each material, layer, region, electrode, pad, pattern, structure or process, respectively.

The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

Spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. Hereinafter, a direction parallel to an upper surface or a lower surface of a wafer, a substrate or a chip may be referred to as a horizontal direction, and a direction perpendicular to the upper surface or the lower surface of the wafer, the substrate or the chip may be referred to as a vertical direction.

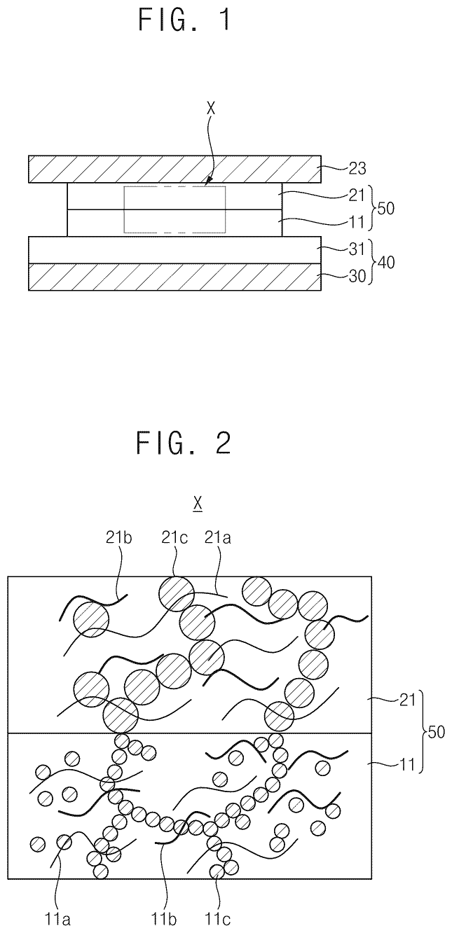

FIG. 1 is a cross-sectional view illustrating a die attach film (DAF) structure in accordance with example embodiments, and FIG. 2 is an enlarged cross-sectional view of region X of FIG. 1.

Referring to FIGS. 1 and 2, the DAF structure may include a dicing film 40, a DAF 50 and a release film 23 sequentially stacked.

The dicing film 40 may include a base film 30 and a pressure sensitive adhesive (PSA) layer 31 sequentially stacked.

The base film 30 may include a plastic material, e.g., polyimide (PI), polyethylene terephthalate (PET), polypropylene (PP), etc. The PSA layer 31 may include, e.g., rubber, acrylate resin, silicon, etc.

In example embodiments, the DAF 50 may include an insulating adhesive layer 11 and a conductive adhesive layer 21 sequentially stacked.

The insulating adhesive layer 11 may include, e.g., an acrylate resin 11a, an epoxy resin 11b and an insulating filler 11c, and may further include an additive, e.g., silane coupling agent.

In example embodiments, the acrylate resin 11a together with the epoxy resin 11b may have a content of about 20 wt % to about 80 wt % in the insulating adhesive layer 11.

In example embodiments, the insulating filler 11c may include an electrically insulating material, e.g., alumina (Al₂O₃) particles, boronitride (BN) particles, aluminum nitride (AlN) particles, silica (SiO₂) particles, diamond particles, magnesium oxide (MgO) particles, silicon nitride (Si₃N₄) particles, etc.

In an example embodiment, the insulating filler 11c may have or may include particles having a first diameter, which may be in a range of about several nanometers to about dozens of micrometers. The insulating adhesive layer 11 including the insulating filler 11c may be bonded to an upper surface of a package substrate structure or an upper surface of a semiconductor chip, which may have concave and convex portions, and the insulating filler 11c may have a small value in the above range in order to fill the concave portion.

In example embodiments, the insulating filler 11c may have a content of about 20 wt % to about 80 wt % in the insulating adhesive layer 11.

The additive may have a content of equal to or less than about 1 wt % in the insulating adhesive layer 11.

The conductive adhesive layer 21 may include, e.g., an acrylate resin 21a, an epoxy resin 21b and a conductive filler 21c, and may further include an additive, e.g., silane coupling agent.

In example embodiments, the conductive filler 21c may include an electrically conductive material having a high thermal conductivity, e.g., a metallic filler such as silver (Ag) particles, copper (Cu) particles, nickel (Ni) particles, etc., or carbon based particles such as carbon nanotube, graphene, etc.

In an example embodiment, the conductive filler 21c or particles thereof may have a second diameter, which may be in a range of about several nanometers to about dozens of micrometers. As the second diameter of the conductive filler 21c increases, a thermal conductivity of the conductive filler 21c may increase, and the second diameter of the conductive filler 21c may have a relatively large value in the above range, particularly in comparison to that of the insulating filler 11c. Thus, in example embodiments, the second diameter of the conductive filler 21c may be greater than the first diameter of the insulating filler 11c.

In example embodiments, the acrylate resin 21a together with the epoxy resin 21b may have a content of about 20 wt % to about 90 wt % in the conductive adhesion layer 21. In example embodiments, the conductive filler 21c may have a content of about 20 wt % to about 80 wt % in the conductive adhesion layer 21.

The additive may have a content of equal to or less than about 1 wt % in the conductive adhesive layer 21.

In an example embodiment, the conductive adhesive layer 21 may have a strength or viscosity greater than a strength or viscosity of the insulating adhesive layer 11. As the conductive adhesive layer 21 has the high strength or viscosity, when a package substrate and a semiconductor chip are bonded with each other or semiconductor chips are bonded with each other using the DAF 50, epoxy molding compound (EMC) included in a molding member that may be formed on the package substrate and cover a sidewall of the DAF 50 may be prevented from permeating into an inactive surface of the semiconductor chip to cause cracks or cracking. Additionally, when the semiconductor chip is bonded to the package substrate by a wire bonding process, wobbling of an edge portion of the semiconductor chip may be prevented so that cracks may not be generated.

The release film 23 may include a film, e.g., PET, PP, etc., and silicon coated on a surface of the film.

The DAF 50 included in the DAF structure may have a stack structure in which the insulating adhesive layer 11 including the insulating filler 11c and the conductive filler 21c and the conductive adhesive layer 21 are stacked. The alumina particles included in the insulating filler 11c may have a thermal conductivity of about 30 W/mK, while the silver particles included in the conductive filler 21c may have a thermal conductivity of about 430 W/mK.

As shown in FIG. 2, in the DAF 50, heat may be transferred through the insulating filler 11c included in the insulating adhesion layer 11 and the conductive filler 21c included in the conductive adhesive layer 21, and for example, if the insulating adhesive layer 11 and the conductive adhesive layer 21 have the same thickness, a total thermal conductivity (kₜₒₜₐₗ) of the DAF 50 may be represented by a thermal conductivity (kₐ) of the insulating adhesive layer 11 and a thermal conductivity (k_{b}) of the conductive adhesive layer 21, as following mathematical formula.

$${k}_{total} = 2 {k}_{a} * {k}_{b} / ( {k}_{a} + {k}_{b} ) \qquad [ Mathematical Formula ]$$

Thus, when compared to a DAF including, e.g., only the insulating adhesive layer 11, the DAF 50 including both the insulating adhesive layer 11 and the conductive adhesive layer 21 may have higher thermal conductivity, which is shown in Table 1.

TABLE 1

| | | thickness ratio | | | k_{b} | | | | | |
|---|---|---|---|---|---|---|---|---|---|---|
| physical properties | | 1:1 | 1:2 | 1:3 | 5 | 15 | 20 | 30 | 45 | 45 |
| thickness | a | 1 | 1 | 1 | 1 | 1 | 1 | 1 | 1 | 1 |
| | b | 1 | 2 | 3 | 1 | 1 | 1 | 1 | 1 | 2 |
| thermal | kₐ | 2 | 2 | 2 | 2 | 2 | 2 | 2 | 2 | 2 |
| conductivity | k_{b} | 15 | 15 | 15 | 5 | 15 | 20 | 30 | 45 | 45 |
| (W/mK) | kₜₒₜₐₗ | 3.53 | 4.74 | 5.17 | 2.86 | 3.53 | 3.64 | 3.75 | 3.83 | 5.51 |

In Table 1, if both of a thickness (a) of the insulating adhesion layer 11 and a thickness (b) of the conductive adhesion layer 21 are 1 (or are otherwise substantially equal) so that a thickness ratio of the insulating adhesion layer 11 and the conductive adhesion layer 21 is 1:1, and a thermal conductivity (kₐ) of the insulating adhesion layer 11 is 2 W/mK and a thermal conductivity (k_{b}) of the conductive adhesion layer 21 is 15 W/mK, then a total thermal conductivity (kₜₒₜₐₗ) of the DAF 50 is 3.53 W/mK, which is greater than the thermal conductivity (kₐ) of the insulating adhesion layer 11.

As the thickness ratio of the insulating adhesion layer 11 and the conductive adhesion layer 21 increases from 1:1 to 1:2 and 1:3, the total thermal conductivity (kₜₒₜₐₗ) of the DAF 50 increases to 4.74 W/mK and 5.17 W/mK, respectively.

If the thickness ratio of the insulating adhesion layer 11 and the conductive adhesion layer 21 is 1:1, as the thermal conductivity (k_{b}) of the conductive adhesion layer 21 increases from 5 to 45, the total thermal conductivity (kₜₒₜₐₗ) of the DAF 50 increases from 2.86 W/mK to 3.83 W/mK.

If the thermal conductivity (kₐ) of the insulating adhesion layer 11 is 2 W/mK and the thermal conductivity (k_{b}) of the conductive adhesion layer 21 is 45 W/mK, and the thickness ratio of the insulating adhesion layer 11 and the conductive adhesion layer 21 changes from 1:1 to 1:2, then the total thermal conductivity (kₜₒₜₐₗ) of the DAF 50 increases from 3.83 W/mK to 5.51 W/mK.

As a result, when compared to the DAF 50 including only the insulating adhesion layer 11, as the DAF 50 includes the conductive adhesion layer 21 as well as the insulating adhesion layer 11, the total thermal conductivity (kₜₒₜₐₗ) of the DAF 50 increases. Particularly, as the thickness ratio of the conductive adhesion layer 21 with respect to the insulating adhesion layer 11 increases, or the thermal conductivity (k_{b}) of the conductive adhesion layer 21 increases, an amount of increase of the total thermal conductivity (kₜₒₜₐₗ) of the DAF 50 may increase.

Copper particles included in the conductive filler 21c may have a thermal conductivity of about 370 W/mK, and the carbon based particles such as carbon nanotube, graphene, etc., may have a thermal conductivity of about 300 W/mK to about 5000 W/mK, which is much greater than that of silver or copper.

As the conductive adhesion layer 21 included in the DAF 50 in accordance with example embodiments may have the thermal conductivity greater than that of the insulating adhesion layer 11, so that the total thermal conductivity of the DAF 50 may increase, however, if the conductive adhesion layer 21 contacts, e.g., a conductive structure of a semiconductor chip bonded to the DAF 50, an electrical short may occur. Thus, the DAF 50 may be bonded to the semiconductor chip such that the insulating adhesion layer 11 may contact an active surface of the semiconductor chip on which the conductive structure is disposed, while the conductive adhesion layer 21 may contact an inactive surface of the semiconductor chip on which no conductive structure is disposed. Accordingly, no electrical short may occur between the semiconductor chip and the conductive adhesion layer 21.

As a result, the DAF 50 in accordance with example embodiments may have an increased thermal conductivity without electrical short to the semiconductor chip.

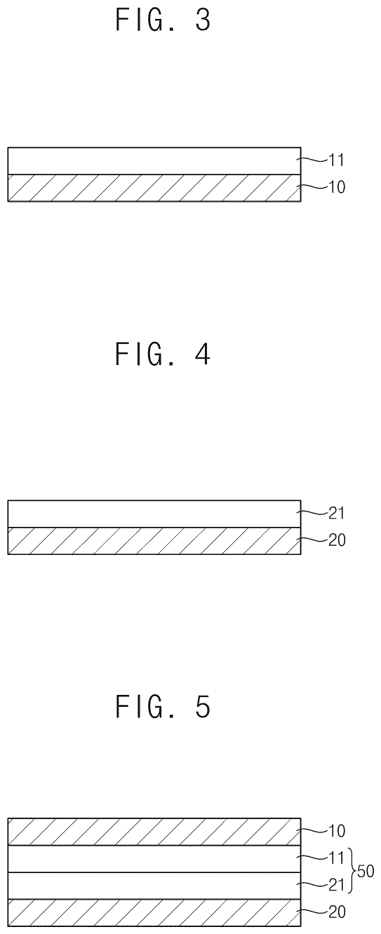

FIGS. 3 to 7 are cross-sectional views illustrating a method of manufacturing a DAF structure in accordance with example embodiments.

Referring to FIG. 3, an insulating adhesion layer 11 may be coated onto a first sacrificial release film 10, and the insulating adhesion layer 11 and the first sacrificial release film 10 may be cut to form a first bonding layer structure.

Referring to FIG. 3 together with FIG. 2, the insulating adhesive layer 11 may include, e.g., an acrylate resin 11a, an epoxy resin 11b and an insulating filler 11c, and may further include an additive, e.g., silane coupling agent.

In example embodiments, the insulating filler 11c may include, e.g., alumina (Al₂O₃) particles, boronitride (BN) particles, aluminum nitride (AlN) particles, silica (SiO₂) particles, diamond particles, magnesium oxide (MgO) particles, silicon nitride (Si₃N₄) particles, etc.

Referring to FIG. 4, a conductive adhesion layer 21 may be coated onto a second sacrificial release film 20, and the conductive adhesion layer 21 and the second sacrificial release film 20 may be cut to form a second bonding layer structure.

Referring to FIG. 3 together with FIG. 2, the conductive adhesive layer 21 may include, e.g., an acrylate resin 21a, an epoxy resin 21b and a conductive filler 21c, and may further include an additive, e.g., silane coupling agent.

In example embodiments, the conductive filler 21c may include an electrically conductive material having a high thermal conductivity, e.g., a metallic filler such as silver (Ag) particles, copper (Cu) particles, nickel (Ni) particles, etc., or carbon based particles such as carbon nanotube, graphene, etc.

Referring to FIG. 5, after flipping the first bonding layer structure, the first and second bonding layer structures may be bonded with each other such that the insulating adhesion layer 11 may contact an upper surface of the conductive adhesion layer 21, and thus a third bonding layer structure may be formed.

Accordingly, a die attach film (DAF) 50 including the conductive adhesion layer 21 and an insulating adhesion layer 11 sequentially stacked may be formed between the second sacrificial release film 20 and the first sacrificial release film 10.

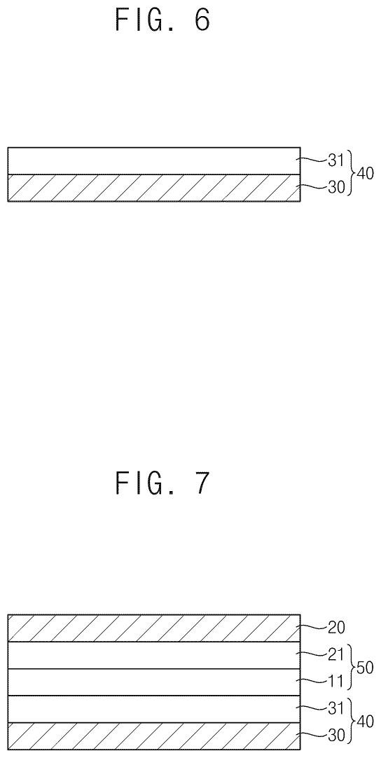

Referring to FIG. 6, a PSA layer 31 may be coated onto a base film 30, and the PSA layer 31 and the base film 30 may be cut to form a dicing film 40.

Referring to FIG. 7, the first sacrificial release film 10 may be removed from the third bonding layer structure, the third bonding layer structure may be flipped, and the third bonding layer structure may be bonded to the dicing film 40 such that the insulating adhesion layer 11 may contact an upper surface of the PSA 31, and thus a fourth bonding layer structure may be formed.

Referring to FIG. 1 again, the second sacrificial release film 20 may be removed from the fourth bonding layer structure, the DAF 50 may be patterned, and a release film 23 may be attached to the conductive adhesion layer 21 to form the DAF structure.

Thus, the DAF structure may include the dicing film 40, the DAF 50 and the release film 23 sequentially stacked, the dicing film 40 may include the base film 30 and the PSA layer 31 sequentially stacked, and the DAF 50 may include the insulating adhesion layer 11 and the conductive adhesion layer 21 sequentially stacked.

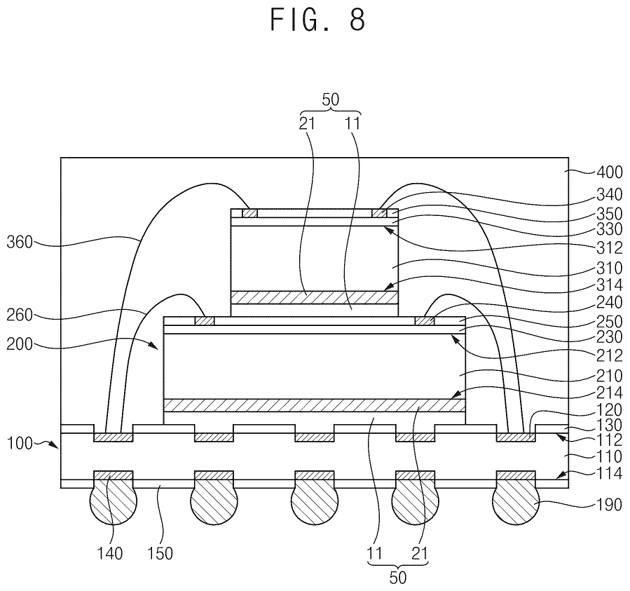

FIG. 8 is a cross-sectional view illustrating a semiconductor package in accordance with example embodiments. The semiconductor package may include the DAF 50 of FIGS. 1 and 2, and thus repeated explanations are omitted herein.

Referring to FIG. 8, the semiconductor package may include a package substrate structure 100, first and second semiconductor chips 200 and 300 stacked in the vertical direction on the package substrate structure 100, the DAF 50, first and second bonding wires 260 and 360, a molding member 400 and a conductive connection member 190.

In example embodiments, the semiconductor package may be a multi-chip package (MCP) including the same type of semiconductor chips or different types of semiconductor chips. Alternatively, the semiconductor package may be a system in package (SIP) including a plurality of semiconductor chips that are stacked or arranged and have an independent function.

In example embodiments, the first and second semiconductor chips 200 and 300 may be the same type of semiconductor chips, and have the same structure but different sizes from each other, however, the inventive concept is not limited thereto. For example, the first and second semiconductor chips 200 and 300 may have different structures from each other, or may have the same structure and the same size.

In example embodiments, the semiconductor package may include two semiconductor chips stacked in the vertical direction on the package substrate structure 100, however, the inventive concept is not limited thereto, and the semiconductor package may include more than two, e.g., four, eight, ten semiconductor chips stacked in the vertical direction.

The package substrate structure 100 may include a package substrate 110 having first and second surfaces 112 and 114 opposite to each other in the vertical direction, a first substrate protective layer 130 on the first surface 112 of the package substrate 110, and a second substrate protective layer 150 on the second surface 114 of the package substrate 110. Each of the first and second substrate protective layers 130 and 150 may include an insulating material, e.g., an oxide such as silicon oxide or an insulating nitride such as silicon nitride.

The package substrate 110 may be, e.g., a printed circuit board (PCB). The PCB may be a multi-level board including circuit patterns, transistors, wirings, vias, contact plugs, conductive pads, etc.

In example embodiments, the circuit patterns may include a first substrate pad 120 adjacent to the first surface 112 of the package substrate 110 and a second substrate pad 140 adjacent to the second surface 114 of the package substrate 110. The first and second substrate pads 120 and 140 may not be covered by the first and second protective layers 130 and 150, respectively, but may be exposed. The term “cover” or “surround” or “fill” as may be used herein may not require completely covering or surrounding or filling the described elements or layers, but may, for example, refer to partially covering or surrounding or filling the described elements or layers, for example, with voids, spaces, or other discontinuities therein. The term “exposed,” may be used to describe relationships between elements and/or certain intermediate processes in fabricating a completed semiconductor device, but may not necessarily require exposure of the particular region, layer, structure or other element in the context of the completed device.

The first substrate pad 120 may transfer electrical signals to semiconductor chips mounted on the package substrate structure 100, and may serve as a bonding pad, e.g., a bonding finger. The second substrate pad 140 may transfer electrical signals to a module substrate under the package substrate structure 100, and may serve as a conductive pad.

The conductive connection member 190 may contact a lower surface of the second substrate pad 140, and an upper portion of the conductive connection member 190 may be covered by the second protective layer 150.

Each of the first and second substrate pads 120 and 140 may include a metal, e.g., copper, aluminum, nickel, etc., and the conductive connection member 190 may include solder that is an alloy of, e.g., tin, silver, lead, etc.

The first semiconductor chip 200 may include a first substrate 210 having first and second surfaces 212 and 214 opposite to each other in the vertical direction, and a first insulating interlayer (not shown) and a second insulating interlayer 230 may be sequentially stacked on the first surface 212 of the first substrate 210.

The first substrate 210 may include a semiconductor material, e.g., silicon, germanium, silicon-germanium, or a III-V group compound semiconductor, e.g., GaP, GaAs, GaSb, etc. In example embodiments, the first substrate 210 may be a silicon-on-insulator (SOI) substrate or a germanium-on-insulator (GOI) substrate.

A circuit device, e.g., a logic device or a memory device may be disposed on the first surface 212 of the first substrate 210. Thus, the first surface 212 may be an active surface of the first semiconductor chip 200, and the second surface 214 of the first semiconductor chip 200 may be an inactive surface of the first semiconductor chip 200.

The memory device may include a volatile memory device such as a DRAM device, an SRAM device, etc., or a non-volatile memory device such as a flash memory device, an EEPROM device, etc. The circuit device may include circuit patterns, and may be covered by the first insulating interlayer.

The second insulating interlayer 230 may include a wiring structure. The wiring structure may include, e.g., wirings, vias, contact plugs, etc.

The first insulating interlayer and the second insulating interlayer 230 may include an oxide, e.g., silicon oxide, an insulating nitride, e.g., silicon nitride, or a low-k dielectric material. The wirings, the vias and the contact plugs may include, e.g., a metal, a metal nitride, a metal silicide, etc.

A first chip pad 240 may be disposed on the second insulating interlayer 230, and may be electrically connected to the wiring structure in the second insulating interlayer 230. A sidewall of the first chip pad 240 may be covered by a first chip protective layer 250 on the second insulating interlayer 230. In example embodiments, a plurality of first chip pads 240 may be spaced apart from each other in the horizontal direction.

The first semiconductor chip 200 may be bonded to an upper surface of the first substrate protective layer 130 and an upper surface of the first substrate pad 120 through the DAF 50 attached to the second surface 214 of the first substrate 210.

The conductive adhesion layer 21 included in the DAF 50 may be bonded to the second surface 214 of the first substrate 210 included in the first semiconductor chip 200, and the insulating adhesion layer 11 included in the DAF 50 may be bonded to the upper surface of the first substrate protective layer 130 and the upper surface of the first substrate pad 120.

As the second surface 214 of the first substrate 210 is the inactive surface, and thus no electrical short may occur even though the conductive adhesion layer 21 including a conductive material is bonded to the second surface 214 of the first substrate 210. Even though the first substrate pad 120 includes a conductive material, the insulating adhesion layer 11 bonded to the first substrate pad 120 does not include a conductive material, so that no electrical short may occur.

The first bonding wire 260 may contact the first substrate pad 120 included in the package substrate structure 100 and the first chip pad 240 included in the first semiconductor chip 200, and may electrically connect the first substrate pad 120 and the first chip pad 240 to each other.

The second semiconductor chip 300 may have a structure substantially the same as or similar to that of the first semiconductor chip 200. Thus, the second semiconductor chip 300 may include a second substrate 310 having first and second surfaces 312 and 314 opposite to each other in the vertical direction, and a third insulating interlayer (not shown) and a fourth insulating interlayer 330 may be sequentially stacked on the first surface 312 of the second substrate 310 in the vertical direction.

A circuit device, e.g., a logic device or a memory device may be disposed on the first surface 312 of the second substrate 310. Thus, the first surface 312 may be an active surface of the second semiconductor chip 300, and the second surface 314 may be an inactive surface of the second semiconductor chip 300. The circuit device may include circuit patterns, and may be covered by the third insulating interlayer. The fourth insulating interlayer 330 may include a wiring structure.

A second chip pad 340 may be disposed on the fourth insulating interlayer 330, and may be electrically connected to the wiring structure in the fourth insulating interlayer 330. A sidewall of the second chip pad 340 may be covered by a second chip protective layer 350 on the fourth insulating interlayer 330. In example embodiments, a plurality of second chip pads 340 may be spaced apart from each other in the horizontal direction.

The second semiconductor chip 300 may be bonded to an upper surface of the first chip protective layer 250 of the first semiconductor chip 200 through the DAF 50 attached to the second surface 314 of the second substrate 310.

The conductive adhesion layer 21 included in the DAF 50 may be bonded to the second surface 314 of the second substrate 310 included in the second semiconductor chip 300, and the insulating adhesion layer 11 included in the DAF 50 may be bonded to the upper surface of the first chip protective layer 250 and an upper surface of the first chip pad 240.

As the second surface 314 of the second substrate 310 is the inactive surface, and thus no electrical short may occur even though the conductive adhesion layer 21 including a conductive material is bonded to the second surface 314 of the second substrate 310. Even though the first substrate pad 120 includes a conductive material, the insulating adhesion layer 11 bonded to the first chip pad 240 does not include a conductive material, so that no electrical short may occur.

The second bonding wire 360 may contact the first substrate pad 120 included in the package substrate structure 100 and the second chip pad 340 included in the second semiconductor chip 300, and may electrically connect the first substrate pad 120 and the second chip pad 340 to each other.

Each of the first and second bonding wires 260 and 360 may include a metal, e.g., copper, aluminum, tungsten, nickel, molybdenum, gold, silver, chrome, tin, titanium, etc.

The molding member 400 may be disposed on the package substrate structure 100, and may cover the first and second semiconductor chips 200 and 300, the DAF 50, and the first and second bonding wires 260 and 360. The molding member 400 may include, e.g., epoxy molding compound (EMC).

In the semiconductor package, the DAF 50 may be interposed between the first semiconductor chip 200 and the package substrate structure 100, and may bond the first semiconductor chip 200 and the package substrate structure 100 to each other. The DAF 50 may also be disposed between the first and second semiconductor chips 200 and 300, and may bond the first and second semiconductor chips 200 and 300 to each other.

The DAF 50 may have a stack structure including the insulating adhesion layer 11 and the conductive adhesion layer 21 stacked in the vertical direction, and as illustrated above with reference to FIGS. 1 and 2, as the conductive adhesion layer 21 includes the conductive filler 21c having a high thermal conductivity, the DAF 50 may have an increased thermal conductivity. Accordingly, the semiconductor package including the DAF 50 may have an enhanced heat emission or dissipation characteristics, which is shown in Table 2 below.

TABLE 2

| | experiment number | | | | | | | | | | |
|---|---|---|---|---|---|---|---|---|---|---|---|
| | 1 | 2 | 3 | 4 | 5 | 6 | 7 | 8 | 9 | 10 | 11 |
| DAF | 0.3 | | | | 2 | 1 | | | 0.7 | | |
| thermal | | | | | | | | | | | |
| conductivity | | | | | | | | | | | |
| DAF | 10 | 5 | 3 | 1 | 10 | 10 | 5 | 3 | 10 | 5 | 3 |
| thickness | | | | | | | | | | | |
| (um) | | | | | | | | | | | |
| chip | 45 | 50 | 52 | 54 | 45 | 45 | 50 | 52 | 45 | 50 | 52 |
| thickness | | | | | | | | | | | |
| (um) | | | | | | | | | | | |
| thermal | 1.54 | 1.37 | 1.31 | 1.23 | 1.26 | 1.36 | 1.26 | 1.23 | 1.32 | 1.28 | 1.25 |
| resistance | | | | | | | | | | | |
| (° C./W) | | | | | | | | | | | |
| improvement | — | 10.7 | 15.2 | 19.8 | 18.1 | 11.6 | 18.4 | 19.9 | 14.4 | 16.9 | 19.0 |
| (%) | | | | | | | | | | | |

In a semiconductor package of Table 2, four semiconductor chips are stacked on the package substrate structure 100, the molding member 400 includes EMC having a thermal conductivity of about 0.88 W/mK, the DAF 50 interposed between the package substrate structure 100 and a lowermost one of the semiconductor chips has a thermal conductivity of about 0.3 W/mK. Table 2 shows a thermal conductivity and a thickness of the DAF 50 interposed between ones of the semiconductor chips at upper levels, respectively (except for one of the semiconductor chips at a lowermost level), and a thermal resistance of the semiconductor package according to the thickness of each of the semiconductor chips. The improvement in heat transfer for each experiment is measured based on a thermal resistance of Experiment 1.

Referring to Table 2, for example, in Experiment 5, if thicknesses of the DAF 50 and the semiconductor chip are the same as those of Experiment 1, and a thermal conductivity of the DAF 50 is 2 W/mK, which is greater than 0.3 W/mk of the DAF 50 in Experiment 1, an improvement of a thermal resistance is about 18.1%. That is, if the DAF 50 has an increased thermal conductivity due to the conductive adhesion layer 21, then the semiconductor package including the DAF 50 may have a decreased thermal resistance so as to have an enhanced heat emission or dissipation characteristics.

Even though the DAF 50 includes the conductive adhesion layer 21, the conductive adhesion layer 21 may be bonded to the second surface 214, which is the inactive surface of the first semiconductor chip 200, and the second surface 314, which is the inactive surface of the second semiconductor chip 300, so that no electrical short may occur.

The insulating adhesion layer 11 included in the DAF 50 may include the insulating filler 11c having a relatively small diameter, and thus, even if the insulating adhesion layer 11 is bonded to the upper surfaces of the first substrate pad 120 and the first substrate protective layer 130 having different heights from each other, no void may be generated between the DAF 50 and the package substrate structure 100.

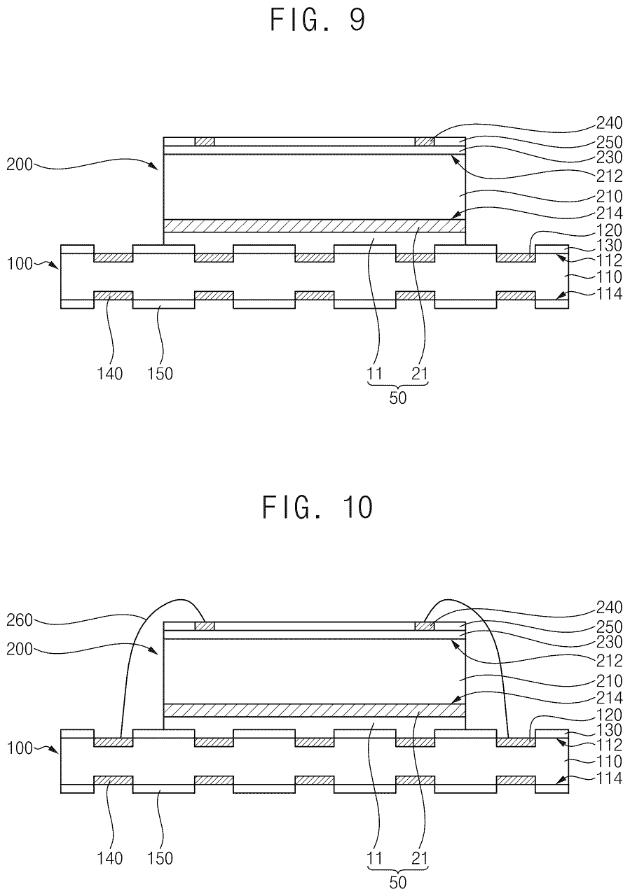

FIGS. 9 to 11 are cross-sectional views illustrating a method of manufacturing a semiconductor package in accordance with example embodiments. In this method, the DAF structure illustrated with reference to FIGS. 1 and 2 may be used, and thus repeated explanations of the DAF structure are omitted herein.

Referring to FIG. 9, a first semiconductor chip 200 may be bonded to an upper surface of the package substrate structure 100.

Particularly, a lower surface of the dicing film 40 included in the DAF structure shown in FIGS. 1 and 2 may be attached to an upper surface of a ring frame, the release film 23 included in the DAF structure may be removed, and a first wafer may be bonded to an upper surface of the conductive adhesion layer 21 included in the DAF structure. A surface of the first wafer bonded to the upper surface of the conductive adhesion layer 21 may be an inactive surface at which no conductive structure is disposed.

The first wafer may be singulated into a plurality of first semiconductor chips 200 by, e.g., a sawing process, and each of the first semiconductor chips 200 may be picked up. During the picking up of each of the first semiconductor chips 200, the dicing film 40 included in the DAF structure may lose adhesion by, e.g., ultraviolet (UV) light to be separated from the DAF 50.

A lower surface of the insulating adhesion layer 11 included in the DAF 50 attached to the first semiconductor chip 200 may be bonded to an upper surface of the package substrate structure 100, so that the first semiconductor chip 200 may be bonded to the package substrate structure 100.

In example embodiments, the package substrate structure 100 may include a package substrate 110 having first and second surfaces 112 and 114 opposite to each other in the vertical direction, a first substrate protective layer 130 on the first surface 112 of the package substrate 110, and a second substrate protective layer 150 on the second surface 114 of the package substrate 110.

The package substrate 110 may be, e.g., a PCB, which may include various circuit patterns at a plurality of levels. In example embodiments, the circuit patterns may include a first substrate pad 120 adjacent to the first surface 112 of the package substrate 110 and a second substrate pad 140 adjacent to the second surface 114 of the package substrate 110. A plurality of first substrate pads 120 may be spaced apart from each other in the horizontal direction, and a plurality of second substrate pads 140 may be spaced apart from each other in the horizontal direction.

The lower surface of the insulating adhesion layer 11 included in the DAF 50 may be bonded to the first surface 112 of the package substrate 110 and an upper surface of the first substrate protective layer 130, which may have a height difference. However, the insulating filler 11c included in the insulating adhesion layer 11 may have or may include particles having a relatively small diameter (e.g., in comparison to the conductive filler 21c), so as to sufficiently or substantially fill a space that may be formed by the first surface 112 of the package substrate 110 and the upper surface of the first substrate protective layer 130.

The first substrate pads 120 including a conductive material may be disposed on the first surface 112 of the package substrate 110, however, the insulating adhesion layer 11 bonded to the upper surfaces of the first substrate pads 120 may not include a conductive material, so that an electrical short may not occur.

The first semiconductor chip 200 may include a first substrate 210 having first and second surfaces 212 and 214 opposite to each other in the vertical direction, and a first insulating interlayer and a second insulating interlayer 230 may be sequentially stacked on the first surface 212 of the first substrate 210.

A circuit device including circuit patterns may be disposed on the first surface 212 of the first substrate 210. Thus, the first surface 212 may be an active surface of the first semiconductor chip 200, and the second surface 214 of the first semiconductor chip 200 may be an inactive surface of the first semiconductor chip 200. The circuit patterns may be covered by the first insulating interlayer, and the second insulating interlayer 230 may include a wiring structure.

A first chip pad 240 may be disposed on the second insulating interlayer 230, and may be electrically connected to the wiring structure in the second insulating interlayer 230. A sidewall of the first chip pad 240 may be covered by a first chip protective layer 250 on the second insulating interlayer 230. In example embodiments, a plurality of first chip pads 240 may be spaced apart from each other in the horizontal direction.

An upper surface of the conductive adhesion layer 21 included in the DAF 50 may be bonded to the second surface 214 of the first substrate 210 included in the first semiconductor chip 200. The second surface 214 of the first substrate 210 may be an inactive surface at which no conductive structure is disposed, and thus, even though the conductive adhesion layer 21 including a conductive material contacts the second surface 214 of the first substrate 210, no electrical short may occur.

Referring to FIG. 10, a wire bonding process may be performed, and thus a first bonding wire 260 may contact the first substrate pad 120 included in the package substrate structure 100 and the first chip pad 240 included in the first semiconductor chip 200, so that the first substrate pad 120 and the first chip pad 240 may be electrically connected to each other.

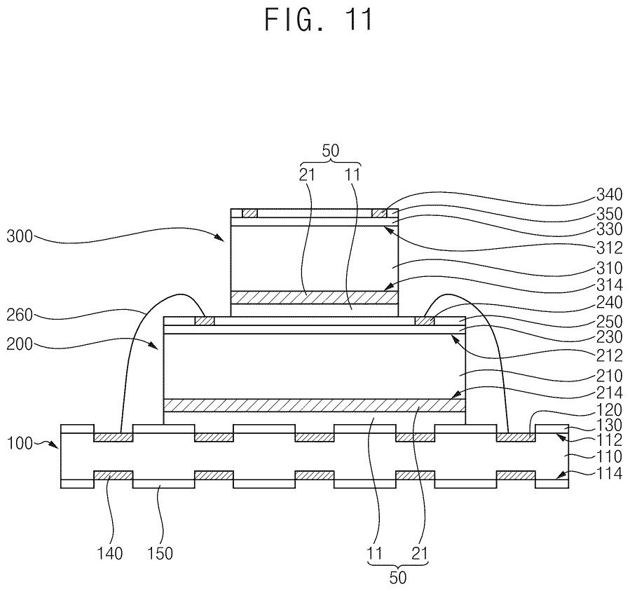

Referring to FIG. 11, a second semiconductor chip 300 may be stacked on the first semiconductor chip 200.

In example embodiments, processes substantially the same as or similar to those illustrated with respect to FIG. 9 may be performed so that the second semiconductor chip 300 may be stacked on the first semiconductor chip 200.

Particularly, a lower surface of the dicing film 40 included in the DAF structure shown in FIGS. 1 and 2 may be attached to an upper surface of a ring frame, the release film 23 included in the DAF structure may be removed, and a second wafer may be bonded to an upper surface of the conductive adhesion layer 21 included in the DAF structure. A surface of the second wafer bonded to the upper surface of the conductive adhesion layer 21 may be an inactive surface at which no conductive structure is disposed.

The second wafer may be singulated into a plurality of second semiconductor chips 300 by, e.g., a sawing process, and each of the second semiconductor chips 300 may be picked up. During the picking up of each of the second semiconductor chips 300, the dicing film 40 included in the DAF structure may lose adhesion by, e.g., ultraviolet (UV) light to be separated from the DAF 50.

A lower surface of the insulating adhesion layer 11 included in the DAF 50 attached to the second semiconductor chip 300 may be bonded to an upper surface of the first semiconductor chip 200, so that the second semiconductor chip 300 may be bonded to the first semiconductor chip 200.

The second semiconductor chip 300 may include a second substrate 310 having first and second surfaces 312 and 314 opposite to each other in the vertical direction, and a third insulating interlayer and a fourth insulating interlayer 330 may be sequentially stacked on the first surface 312 of the second substrate 310 in the vertical direction.

A circuit device including circuit patterns may be disposed on the first surface 312 of the second substrate 310. Thus, the first surface 312 may be an active surface of the second semiconductor chip 300, and the second surface 314 may be an inactive surface of the second semiconductor chip 300. The circuit patterns may be covered by the third insulating interlayer, and the fourth insulating interlayer 330 may include a wiring structure.

A second chip pad 340 may be disposed on the fourth insulating interlayer 330, and may be electrically connected to the wiring structure in the fourth insulating interlayer 330. A sidewall of the second chip pad 340 may be covered by a second chip protective layer 350 on the fourth insulating interlayer 330. In example embodiments, a plurality of second chip pads 340 may be spaced apart from each other in the horizontal direction.

An upper surface of the conductive adhesion layer 21 included in the DAF 50 may be bonded to the second surface 314 of the second substrate 310 included in the second semiconductor chip 300. As the second surface 314 of the second substrate 310 is the inactive surface, and thus no electrical short may occur even though the conductive adhesion layer 21 including a conductive material is bonded to the second surface 314 of the second substrate 310.

A lower surface of the insulating adhesion layer 11 included in the DAF 50 may be bonded to an upper surface of the first chip protective layer 250 of the first semiconductor chip 200.

Referring to FIG. 8 again, a wire bonding process may be performed, and thus a second bonding wire 360 may contact the first substrate pad 120 included in the package substrate structure 100 and the second chip pad 340 included in the second semiconductor chip 300, so that the first substrate pad 120 and the second chip pad 340 may be electrically connected to each other.

A molding member 400 may be formed on the package substrate structure 100 to cover the first and second semiconductor chips 200 and 300, the DAF 50, and the first and second bonding wires 260 and 360.

A conductive connection member 190 may be formed on the second surface 114 of the package substrate 110 to contact the second substrate pad 140, so that the semiconductor package may be manufactured.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A die attach film (DAF) structure comprising:
a dicing film;
an insulating adhesion layer comprising an upper surface and a lower surface opposite the upper surface, the lower surface of the insulating adhesion layer contacting an upper surface of the dicing film, the insulating adhesion layer comprising an insulating filler; and
a conductive adhesion layer contacting the upper surface of the insulating adhesion layer, the conductive adhesion layer comprising a conductive filler.

2. The DAF structure according to claim 1, wherein the conductive filler comprises silver (Ag) particles, copper (Cu) particles, nickel (Ni) particles, carbon nanotubes, or graphene.

3. The DAF structure according to claim 1, wherein the conductive adhesion layer further comprises an acrylate resin and an epoxy resin.

4. The DAF structure according to claim 3, wherein the conductive adhesion layer comprises the conductive filler in an amount of about 20 wt % to about 80 wt %, and the acrylate resin and the epoxy resin collectively in an amount of about 20 wt % to about 80 wt %.

5. The DAF structure according to claim 4, wherein the conductive adhesion layer further comprises an additive in an amount of equal to or less than about 1 wt %.

6. The DAF structure according to claim 1, wherein the insulating filler comprises alumina (Al₂O₃) particles, boronitride (BN) particles, aluminum nitride (AlN) particles, silica (SiO₂) particles, diamond particles, magnesium oxide (MgO) particles, or silicon nitride (Si₃N₄) particles.

7. The DAF structure according to claim 1, wherein the insulating adhesion layer further includes an acrylate resin and an epoxy resin.

8. The DAF structure according to claim 7, wherein the insulating adhesion layer comprises the insulating filler in an amount of about 20 wt % to about 80 wt %, and the acrylate resin and the epoxy resin collectively in an amount of about 20 wt % to about 80 wt %.

9. The DAF structure according to claim 8, wherein the insulating adhesion layer further comprises an additive in an amount of equal to or less than about 1 wt %.

10. The DAF structure according to claim 1, wherein a diameter of respective particles of the conductive filler is greater than or equal to a diameter of respective particles of the insulating filler.

11. The DAF structure according to claim 1, wherein the dicing film comprises a base film and a pressure sensitive adhesive (PSA) layer sequentially stacked.

12. The DAF structure according to claim 1, further comprising:
a release film contacting an upper surface of the conductive adhesion layer that is opposite the insulating adhesion layer.

13. A semiconductor package comprising:
a package substrate structure;
a first die attach film (DAF) bonded to an upper surface of the package substrate structure; and
a first semiconductor chip comprising a lower surface that is bonded to an upper surface of the first DAF opposite the package substrate structure,
wherein the first DAF comprises:
a first insulating adhesion layer comprising an upper surface and a lower surface, the lower surface of the first insulating adhesion layer contacting the upper surface of the package substrate structure, the first insulating adhesion layer comprising a first insulating filler; and
a first conductive adhesion layer contacting the upper surface of the first insulating adhesion layer and the lower surface of the first semiconductor chip, the first conductive adhesion layer comprising a first conductive filler.

14. The semiconductor package according to claim 13, wherein the package substrate structure comprises:
a package substrate having first and second surfaces opposite to each other in a vertical direction in which the first DAF and the first semiconductor chip are stacked thereon;
a substrate pad adjacent to the first surface of the package substrate; and
a substrate protective layer on the first surface of the package substrate,
wherein an upper surface of the substrate pad is exposed by the substrate protective layer, and
wherein the first insulating adhesion layer contacts the substrate pad and the substrate protective layer.

15. The semiconductor package according to claim 14, wherein the first semiconductor chip comprises:
a substrate having first and second surfaces opposite to each other in the vertical direction, wherein the first surface of the substrate comprises at least one conductive circuit pattern and the second surface of the substrate is free of conductive structures; and
a chip pad on the first surface of the substrate and electrically connected to the at least one conductive circuit pattern of the first semiconductor chip,
wherein the first conductive adhesion layer contacts the second surface of the substrate.

16. The semiconductor package according to claim 15, further comprising a bonding wire contacting the chip pad and the substrate pad, wherein the bonding wire electrically connects the chip pad and the substrate pad to each other.

17. The semiconductor package according to claim 13, further comprising:
a second DAF bonded to an upper surface of the first semiconductor chip that is opposite the lower surface thereof; and
a second semiconductor chip comprising a lower surface that is bonded to an upper surface of the second DAF opposite the first semiconductor chip,
wherein the second DAF comprises:
a second insulating adhesion layer comprising a lower surface contacting the upper surface of the first semiconductor chip and an upper surface opposite the lower surface, the second insulating adhesion layer comprising a second insulating filler; and
a second conductive adhesion layer contacting the upper surface of the second insulating adhesion layer and the lower surface of the second semiconductor chip, the second conductive adhesion layer comprising a second conductive filler.

18. The semiconductor package according to claim 17, wherein the second semiconductor chip comprises:
a substrate having first and second surfaces opposite to each other in a vertical direction, wherein the first surface of the substrate comprises at least one conductive circuit pattern and the second surface of the substrate is free of conductive structures; and
a chip pad on the first surface of the substrate and electrically connected to the at least one conductive circuit pattern of the second semiconductor chip,
wherein the second conductive adhesion layer contacts the second surface of the substrate.

19. A semiconductor package comprising:
a package substrate structure comprising a substrate pad;
a first die attach film (DAF) bonded to an upper surface of the package substrate structure;
a first semiconductor chip comprising a lower surface that is bonded to an upper surface of the first DAF opposite the package substrate structure, the first semiconductor chip comprising a first chip pad at an upper portion thereof;
a second DAF bonded to an upper surface of the first semiconductor chip that is opposite the lower surface thereof;
a second semiconductor chip comprising a lower surface that is bonded to an upper surface of the second DAF opposite the first semiconductor chip, the second semiconductor chip comprising a second chip pad at an upper portion thereof;
a first bonding wire contacting the first chip pad and the substrate pad, wherein the first bonding wire electrically connects the first chip pad and the substrate pad to each other;
a second bonding wire contacting the second chip pad and the substrate pad, wherein the second bonding wire electrically connects the second chip pad and the substrate pad to each other; and
a molding member on the package substrate structure and on the first and second semiconductor chips, the first and second bonding wires, and the first and second DAFs,
wherein the first DAF comprises:
a first insulating adhesion layer comprising an upper surface and a lower surface opposite the upper surface, the lower surface of the first insulating adhesion layer contacting the upper surface of the package substrate structure, the first insulating adhesion layer comprising a first insulating filler; and
a first conductive adhesion layer contacting the upper surface of the first insulating adhesion layer and the lower surface of the first semiconductor chip, the first conductive adhesion layer comprising a first conductive filler, and
wherein the second DAF comprises:
a second insulating adhesion layer comprising an upper surface and a lower surface opposite the upper surface, the lower surface of the second insulating adhesion layer contacting the upper surface of the first semiconductor chip, the second insulating adhesion layer comprising a second insulating filler; and
a second conductive adhesion layer contacting the upper surface of the second insulating adhesion layer and the lower surface of the second semiconductor chip, the second conductive adhesion layer comprising a second conductive filler.

20. The semiconductor package according to claim 19, wherein each of the first and second conductive fillers comprises silver (Ag) particles, copper (Cu) particles, nickel (Ni) particles, carbon nanotubes, or graphene, and
wherein each of the first and second insulating fillers comprises alumina (Al₂O₃) particles, boronitride (BN) particles, aluminum nitride (AlN) particles, silica (SiO₂) particles, diamond particles, magnesium oxide (MgO) particles, or silicon nitride (Si₃N₄) particles.
